(19) United States
(12) Patent Application Publication
(10) Pub. No.: US 2026/0371547 A1
(43) Pub. Date: Nov. 19, 2026

(54) SEMICONDUCTOR DEVICE

(71) Applicant: RAPIDUS CORPORATION, Tokyo (JP)

(72) Inventor: Shingo Nakazawa, Albany, NY (US)

(21) Appl. No.: 19/744,229

(22) Filed: Jul. 16, 2026

Related U.S. Application Data
(63) Continuation of application No. PCT/JP2024/029064, filed on Aug. 15, 2024.
(60) Provisional application No. 63/637,583, filed on Apr. 23, 2024.

(51) Int. Cl. H10B 10/00; G11C 11/419; H10D 30/00; H10D 30/43; H10D 62/10; H10W 20/41; H10W 20/43

(52) U.S. Cl. CPC H10B 10/12; G11C 11/419; H10D 30/43; H10D 30/502; H10D 62/121; H10W 20/43; H10W 20/435

(57) ABSTRACT

A semiconductor device includes: a first inverter; a second inverter; a first PG transistor connected to a first bit line; a second PG transistor connected to a second bit line; a third PG transistor connected to a first complementary bit line; and a fourth PG transistor connected to a second complementary bit line. The first PG transistor and the second PG transistor share a first gate, and the third PG transistor and the fourth PG transistor share a second gate.

### TECHNICAL FIELD

The present invention relates to a semiconductor device.

### BACKGROUND ART

A static random access memory (SRAM) is widely used as a semiconductor device. Since the SRAM has a high reading speed and a high writing speed, the SRAM is used for applications in which a high processing speed is required. As the SRAM, a dual port static random access memory (SRAM) including two ports for reading and writing data is known (see, for example, Non Patent Literature 1). In the dual port SRAM, one cell is constituted by eight transistors consisting of four pass gate (PG) transistors (Tr), two pull-up (PU) transistors, and two pull-down (PD) transistors. In the dual port SRAM described in Non Patent Literature 1, in order to improve an integration density (to perform miniaturization and high integration) by downsizing an element and reducing a cell area, a structure has been proposed in which each transistor is formed of a fin field effect transistor (FinFET).

Furthermore, in order to improve an integration density by downsizing an element and reducing a cell area, as a single port SRAM, a configuration has been proposed in which each of pull-up and pull-down complementary metal-oxide-semiconductor (CMOS) inverters is formed of a complementary field-effect transistor (CFET) (see, for example, Patent Literature 2).

### CITATION LIST

### Non Patent Literature

Non Patent Literature 1: K. Nii, et al., 2RW Dual-port SRAM Design Challenges in Advanced Technology Nodes, IEDM2015

Non Patent Literature 2: H. Liu, et al., IEEE TRANSACTIONS ON ELECTRON DEVICES, VOL. 70, NO. 3, MARCH 2023

### SUMMARY OF INVENTION

### Technical Problem

However, the dual port SRAM having the configuration described in Non Patent Literature 1 can miniaturize a transistor by the FinFET, but since eight transistors are disposed on a plane, there is no change in the number of transistors. Therefore, in the configuration described in Non Patent Literature 1, there is a limit to improvement of the integration density.

In addition, in the single port SRAM having the configuration described in Non Patent Literature 2, a pass gate Tr is formed adjacent to the CFET including a pull-up Tr and a pull-down Tr. However, in the pass gate Tr, the pull-up Tr is formed only on a lower layer side, and a wiring for contact between a gate electrode of the CMOS inverter and a source/drain is formed on an upper layer side of a region where the pass gate Tr is formed. As described above, in the configuration described in Non Patent Literature 2, it is necessary to remove the upper layer side of the region where the pass gate Tr is formed in order to form the wiring for contact. Therefore, in the configuration described in Non Patent Literature 2, four pass gates Tr for forming the dual port SRAM cannot be formed. Therefore, in the configuration described in Non Patent Literature 2, the integration density of the dual port SRAM cannot be improved by the CFET structure.

In order to solve the above-described problem, the present invention provides a semiconductor device capable of improving an integration density.

### Solution to Problem

A semiconductor device of the present invention includes: a first inverter and a second inverter that are cross-connected; a first conductivity type first pass gate transistor disposed between a first bit line and the first and second inverters; a second conductivity type second pass gate transistor disposed between a second bit line and the first and second inverters; a first conductivity type third pass gate transistor disposed between a first complementary bit line and the first and second inverters; and a second conductivity type fourth pass gate transistor disposed between a second complementary bit line and the first and second inverters. The first pass gate transistor and the second pass gate transistor share a first gate connected to a word line, and the third pass gate transistor and the fourth pass gate transistor share a second gate connected to the word line.

### Advantageous Effects of Invention

According to the present invention, it is possible to provide a semiconductor device capable of improving an integration density.

### BRIEF DESCRIPTION OF DRAWINGS

FIG. 1 is an equivalent circuit diagram of a bit cell of a dual port SRAM.

FIG. 2 is a planar arrangement diagram of a SRAM array including the dual port SRAM.

FIG. 3 is a planar arrangement diagram of a transistor of a SRAM of a first embodiment.

FIG. 4 is a cross-sectional view taken along line A-A of the SRAM illustrated in FIG. 3.

FIG. 5 is a cross-sectional view taken along line B-B of the SRAM illustrated in FIG. 3.

FIG. 6 is a cross-sectional view taken along line C-C of the SRAM illustrated in FIG. 3.

FIG. 7 is a diagram illustrating a relationship among a threshold voltage of an NMOS transistor, a threshold voltage of a PMOS transistor, and a standby voltage of a word line.

FIG. 8 is a planar arrangement diagram of a SRAM array including a word line and a sense amplifier.

FIG. 9 is a simple timing chart of a SRAM in a case where Read is performed from a port A.

FIG. 10 is a simple timing chart of a SRAM in a case where Read is performed from a port B.

FIG. 11 is a simple timing chart of a SRAM in a case where Write is performed from a port A.

FIG. 12 is a simple timing chart of a SRAM in a case where Write is performed from a port B.

FIG. 13 is a planar arrangement diagram of a transistor of a SRAM of a second embodiment.

FIG. 14 is a simple timing chart of Read and Write of a SRAM of a third embodiment.

FIG. 15 is a diagram illustrating a comparison between a standby voltage of a bit line in the SRAM of the third embodiment and a standby voltage of a SRAM bit line of the first embodiment.

### DESCRIPTION OF EMBODIMENTS

Hereinafter, embodiments of a semiconductor device will be described with reference to the drawings, but the present invention is not limited to the following examples. Note that, in the following description, only components of a main part of the semiconductor device are illustrated in the drawings, and description of the other components such as an insulating layer is omitted.

The description will be given in the following order.
1. First embodiment of semiconductor device
2. Second embodiment of semiconductor device
3. Third embodiment of semiconductor device

### 1. First Embodiment of Semiconductor Device

Hereinafter, a first embodiment of a semiconductor device of the present invention will be described.

### [Circuit Diagram of Semiconductor Device]

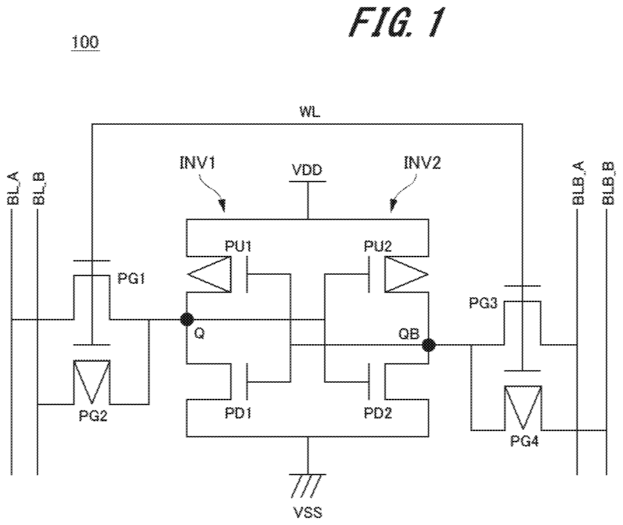

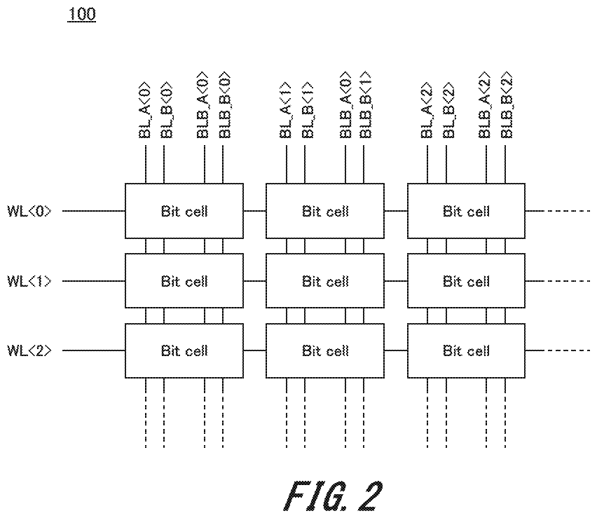

FIG. 1 illustrates an equivalent circuit diagram of a bit cell of a dual port static random access memory (SRAM) as an example of the semiconductor device. FIG. 2 illustrates a planar arrangement diagram of a SRAM array including the dual port SRAM.

As illustrated in FIG. 1, a dual port SRAM cell 100 (hereinafter, also simply referred to as a SRAM 100) includes eight transistors (8Tr) in one bit cell. Among the 8Tr of the SRAM 100, four transistors constitute a first complementary metal-oxide-semiconductor (CMOS) inverter INV1 (hereinafter, referred to as a first inverter INV1) and a second CMOS inverter INV2 (hereinafter, referred to as a second inverter INV2). Furthermore, the SRAM 100 includes four transistors that control input to the SRAM 100 and output from the SRAM 100. Note that, in the SRAM 100, a first conductivity type is n-type, and a second conductivity type is p-type.

In addition, as illustrated in FIG. 2, in the SRAM array using the 8Tr SRAM 100, SRAM 100 bit cells are disposed in a row direction and a column direction as a plan view. A column of the SRAM array is formed by one first bit line pair consisting of a first bit line BL_A and a first complementary bit line BLB_A and one second bit line pair consisting of a second bit line BL_B and a second complementary bit line BLB_B. A row of the SRAM array is formed by a word line WL. Therefore, the SRAM 100 is disposed along the word line WL. FIG. 2 illustrates an example of the SRAM array, and illustrates a word line WL<0>, a word line WL<1>, and a word line WL<2> as three word lines WL. In addition, as three sets of the first bit line pairs and three sets of the second bit line pairs, a first bit line BL_A<0> and a first complementary bit line BLB_A<0>, a first bit line BL_A<1> and a first complementary bit line BLB_A<1>, a first bit line BL_A<2> and a first complementary bit line BLB_A<2>, a second bit line BL_B<0> and a second complementary bit line BLB_B<0>, a second bit line BL_B<1> and a second complementary bit line BLB_B<1>, and a second bit line BL_B<2> and a second complementary bit line BLB_B<2> are illustrated.

One cell of the SRAM array is disposed between one pair of bit lines consisting of the first bit line pair and one pair of bit lines consisting of the second bit line pair. Therefore, as illustrated in FIG. 1, the SRAM 100 is disposed between the first bit line BL_A and the first complementary bit line BLB_A constituting the first bit line pair and between the second bit line BL_B and the second complementary bit line BLB_B constituting the second bit line pair.

As illustrated in FIG. 1, the first inverter INV1 and the second inverter INV2 are cross-connected. That is, an output of the first inverter INV1 is connected to an input of the second inverter INV2. Similarly, an output of the second inverter INV2 is connected to an input of the first inverter INV1.

The first inverter INV1 constituting the SRAM 100 includes a pull-up p-type metal oxide semiconductor (PMOS) transistor PU1 (hereinafter, referred to as a transistor PU1) and a pull-down n-type metal oxide semiconductor (NMOS) transistor PD1 (hereinafter, referred to as a transistor PD1). The second inverter INV2 includes a pull-up PMOS transistor PU2 (hereinafter, referred to as a transistor PU2) and a pull-down NMOS transistor PD2 (hereinafter, referred to as a transistor PD2).

The SRAM 100 includes a pass gate NMOS transistor PG1 (hereinafter, referred to as a transistor PG1) connected between the first bit line BL_A and the first and second inverters INV1 and INV2. In addition, the SRAM 100 includes a pass gate PMOS transistor PG2 (hereinafter, referred to as a transistor PG2) connected between the second bit line BL_B and the first and second inverters INV1 and INV2. One source/drain of the transistor PG1 is connected to the first bit line BL_A. One source/drain of the transistor PG2 is connected to the second bit line BL_B. The other source/drain of the transistor PG1 and the other source/drain of the transistor PG2 are commonly connected to an output node Q of the first inverter INV1 and an input (gate) of the second inverter INV2.

Furthermore, the SRAM 100 includes a pass gate NMOS transistor PG3 (hereinafter, referred to as a transistor PG3) connected between the first complementary bit line BLB_A and the first and second inverters INV1 and INV2. In addition, the SRAM 100 includes a pass gate PMOS transistor PG4 (hereinafter, referred to as a transistor PG4) connected between the second complementary bit line BLB_B and the first and second inverters INV1 and INV2. One source/drain of the transistor PG3 is connected to the first complementary bit line BLB_A. One source/drain of the transistor PG4 is connected to the second complementary bit line BLB_B. The other source/drain of the transistor PG3 and the other source/drain of the transistor PG4 are commonly connected to an output node QB of the second inverter INV2 and an input (gate) of the first inverter INV1.

Hereinafter, the transistor PG1 and the transistor PG3 connected to the first bit line BL_A and the first complementary bit line BLB_A, respectively, are referred to as a port A. In addition, the transistor PG2 and the transistor PG4 connected to the second bit line BL_B and the first complementary bit line BLB_A, respectively, are referred to as a port B.

Gates of the transistors PG1, PG2, PG3, and PG4 are connected to a word line WL connecting the SRAM 100 in a row of the SRAM array.

The transistor PG1 and the transistor PG2 share a gate electrode. Therefore, the gates of the transistor PG1 and the transistor PG2 are connected to a word line WL by a common electrode. The transistor PG3 and the transistor PG4 share a gate electrode. Therefore, the gates of the transistor PG3 and the transistor PG4 are connected to a word line WL by a common electrode.

In the SRAM 100, both the first inverter INV1 and the second inverter INV2 are coupled between a power supply voltage VDD and a reference potential VSS.

That is, in the SRAM 100, one source/drain of the transistor PU1 is connected to the power supply voltage VDD, and the other source/drain of the transistor PU1 is connected to a source/drain of the transistor PD1. One source/drain of the transistor PD1 is connected to the reference potential VSS, and the other source/drain of the transistor PD1 is connected to a source/drain of the transistor PU1. One source/drain of the transistor PU2 is connected to the power supply voltage VDD, and the other source/drain of the transistor PU2 is connected to a source/drain of the transistor PD2. One source/drain of the transistor PD2 is connected to the reference potential VSS, and the other source/drain of the transistor PD2 is connected to a source/drain of the transistor PU2.

The transistor PU1 and the transistor PD1 share a gate. The transistor PU2 and the transistor PD2 share a gate. The common gate between the transistor PU1 and the transistor PD1 is an input of the first inverter INV1. The common gate between the transistor PU2 and the transistor PD2 is an input of the second inverter INV2. A connection portion (contact) between a source/drain of the transistor PU1 and a source/drain of the transistor PD1 is an output node Q of the first inverter INV1. A connection portion (contact) between a source/drain of the transistor PU2 and a source/drain of the transistor PD2 is an output node QB of the second inverter INV2.

### [Configuration of Semiconductor Device]

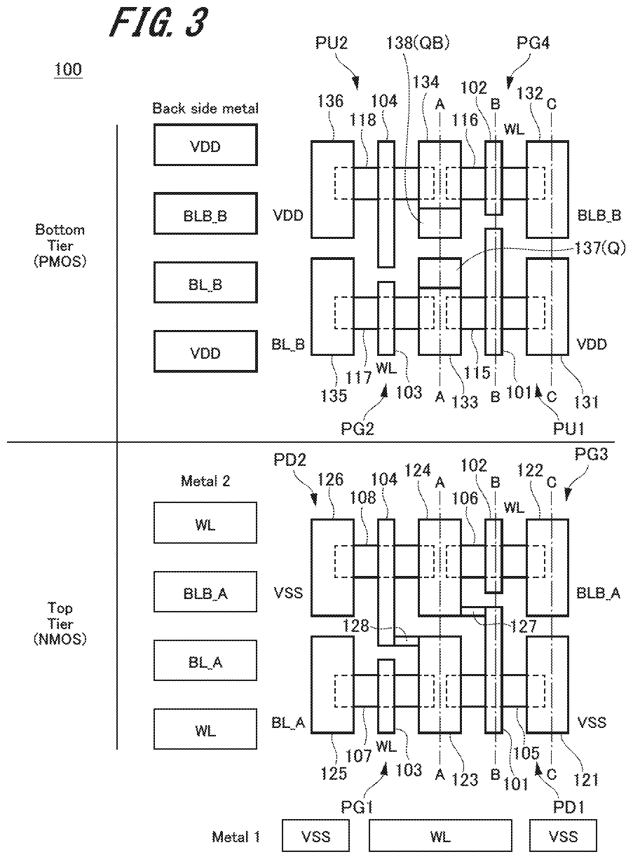

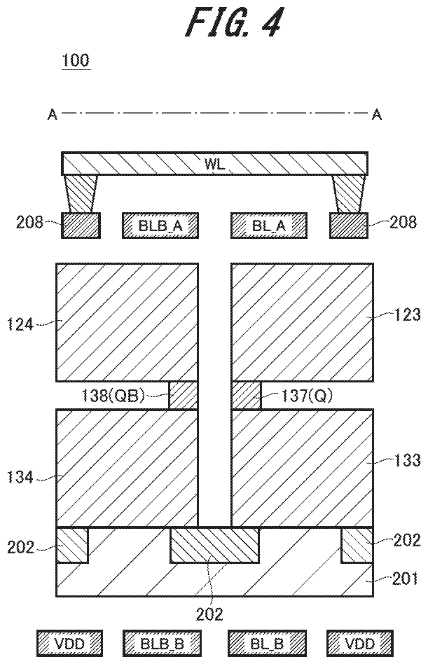

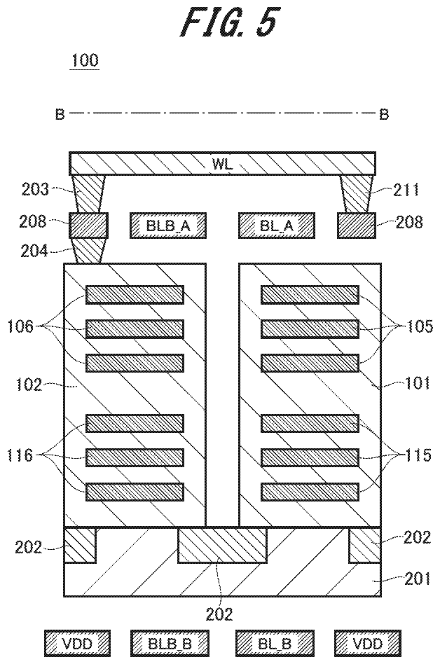

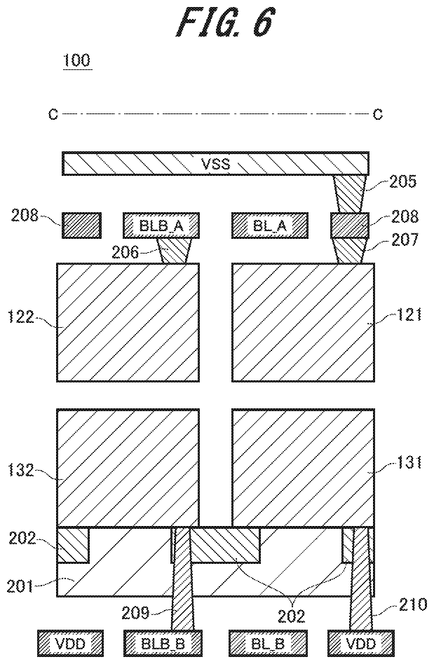

Next, a configuration of the SRAM 100 will be described. FIG. 3 illustrates a planar arrangement diagram of transistors of the SRAM 100. FIGS. 4, 5, and 6 illustrate cross-sectional views of the SRAM 100. The planar arrangement diagram illustrated in FIG. 3 is a planar arrangement diagram of elements of an upper layer (Top Tier) and a lower layer (Bottom Tier) of the SRAM 100. FIG. 4 is a cross-sectional view taken along line A-A of the SRAM 100 illustrated in FIG. 3. FIG. 5 is a cross-sectional view taken along line B-B of the SRAM 100 illustrated in FIG. 3. FIG. 6 is a cross-sectional view taken along line C-C of the SRAM 100 illustrated in FIG. 3. Note that, in the drawings illustrated in FIGS. 3 to 6, description of an insulating layer and the like other than a main configuration of the SRAM 100 is omitted unless necessary for description.

As illustrated in FIGS. 4 to 6, the SRAM 100 has a complementary field effect transistor (CFET) structure in which nanosheet transistors (semiconductor elements) having gate all around (GAA)-FET structures are stacked in a vertical direction. Note that, in the semiconductor device, the nanosheet also includes a nanowire.

Therefore, FIG. 3 illustrates planar arrangement of the GAA-FET having a nanosheet structure disposed on an upper layer side of the CFET and a planar arrangement of the GAA-FET having a nanosheet structure disposed on a lower layer side of the CFET.

As illustrated in FIG. 3, in the SRAM 100, the transistor PD1, the transistor PG1, the transistor PD2, and the transistor PG3 which are each formed of NMOS are disposed on the upper layer side of the CFET. In the SRAM 100, the transistor PU1, the transistor PG2, the transistor PU2, and the transistor PG4 which are each formed of PMOS are disposed on the lower layer side of the CFET. In the SRAM 100 illustrated in FIG. 3, the transistor PD1 is formed above the transistor PU1. The transistor PG1 is formed above the transistor PG2. The transistor PD2 is formed above the transistor PU2. The transistor PG3 is formed above the transistor PG4.

The SRAM 100 includes two reference potentials VSS and a word line WL as a wiring (Metal 1) of an uppermost layer (first layer) on a front surface side of the CFET. The SRAM 100 includes two word lines WL, the first bit line BL_A, and the first complementary bit line BLB_A as a wiring (Metal 2) of the second layer on the front surface side of the CFET. Furthermore, the SRAM 100 includes two power supply voltages VDD, the second bit line BL_B, and the second complementary bit line BLB_B as a wiring (Back side metal) on a back surface side of the CFET. Note that, in the SRAM 100, description is given by defining a main surface on a substrate side in a stacking direction of the transistors as the back surface, and defining a main surface on the opposite side to the substrate as the front surface.

As illustrated in FIGS. 3 and 5, gate electrodes 101, 102, 103, and 104 are continuously formed on the upper layer and the lower layer of the CFET. That is, the transistor PD1 and the transistor PU1 have the common gate electrode 101. Similarly, the transistor PG1 and the transistor PG2 have the common gate electrode 103. The transistor PD2 and the transistor PU2 have the common gate electrode 104. The transistor PG3 and the transistor PG4 have the common gate electrode 102.

The gate electrode 103 shared by the transistor PG1 and the transistor PG2 is connected to a word line WL. Similarly, the gate electrode 102 shared by the transistor PG3 and the transistor PG4 is connected to a word line WL.

As illustrated in FIG. 3, the transistor PD1 includes a channel, a semiconductor layer 105 serving as a source/drain, and the gate electrode 101. At one end of the semiconductor layer 105 serving as a source/drain of the transistor PD1, a contact metal 121 that connects the source/drain and the reference potential VSS to each other is disposed. At the other end of the semiconductor layer 105, a contact metal 123 that connects the source/drain of the transistor PD1 and a source/drain of the transistor PG1 to each other is disposed.

The transistor PG1 includes a channel, a semiconductor layer 107 serving as a source/drain, and the gate electrode 103. At one end of the semiconductor layer 107 serving as a source/drain of the transistor PG1, a contact metal 125 that connects the source/drain of the transistor PG1 and the first bit line BL_A to each other is disposed. At the other end of the semiconductor layer 107, the contact metal 123 that connects the source/drain of the transistor PG1 and the source/drain of the transistor PD1 to each other is disposed.

The transistor PG3 includes a channel, a semiconductor layer 106 serving as a source/drain, and the gate electrode 102. At one end of the semiconductor layer 106 serving as a source/drain of the transistor PG3, a contact metal 122 that connects the source/drain of the transistor PG3 and the first complementary bit line BLB_A to each other is disposed. At the other end of the semiconductor layer 106, a contact metal 124 that connects the source/drain of the transistor PG3 and a source/drain of the transistor PD2 to each other is disposed.

The transistor PD2 includes a channel, a semiconductor layer 108 serving as a source/drain, and the gate electrode 104. At one end of the semiconductor layer 108 serving as a source/drain of the transistor PD2, a contact metal 126 that connects the source/drain and the reference potential VSS to each other is disposed. At the other end of the semiconductor layer 108, the contact metal 124 that connects the source/drain of the transistor PD2 and the source/drain of the transistor PG3 to each other is disposed.

The transistor PU1 includes a channel, a semiconductor layer 115 serving as a source/drain, and the gate electrode 101. At one end of the semiconductor layer 115 serving as a source/drain of the transistor PU1, a contact metal 131 that connects the source/drain and the power supply voltage VDD to each other is disposed. At the other end of the semiconductor layer 115, a contact metal 133 that connects the source/drain of the transistor PU1 and a source/drain of the transistor PG2 to each other is disposed.

The transistor PG2 includes a channel, a semiconductor layer 117 serving as a source/drain, and the gate electrode 103. At one end of the semiconductor layer 117 serving as a source/drain of the transistor PG2, a contact metal 135 that connects the source/drain and the second bit line BL_B to each other is disposed. At the other end of the semiconductor layer 117, the contact metal 133 that connects the source/drain of the transistor PG2 and the source/drain of the transistor PU1 to each other is disposed.

The transistor PG4 includes a channel, a semiconductor layer 116 serving as a source/drain, and the gate electrode 102. At one end of the semiconductor layer 116 serving as a source/drain of the transistor PG4, a contact metal 132 that connects the source/drain and the second complementary bit line BLB_B to each other is disposed. At the other end of the semiconductor layer 116, a contact metal 134 that connects the source/drain of the transistor PG4 and a source/drain of the transistor PU2 to each other is disposed.

The transistor PU2 includes a channel, a semiconductor layer 118 serving as a source/drain, and the gate electrode 104. At one end of the semiconductor layer 118 serving as a source/drain of the transistor PU2, a contact metal 136 that connects the source/drain and the power supply voltage VDD to each other is disposed. At the other end of the semiconductor layer 118, the contact metal 134 that connects the source/drain of the transistor PU2 and the source/drain of the transistor PG4 to each other is disposed.

As illustrated in FIGS. 4 to 6, the SRAM 100 is formed on a substrate 201. The substrate 201 includes an insulating layer 202 serving as an element isolation on a surface thereof. The insulating layer 202 is formed between CFET elements formed on the substrate 201 so as to insulate the CFET elements from each other.

The wiring (Metal 1) of the uppermost layer of the SRAM 100 includes a word line WL and the reference potential VSS. The wiring (Metal 2) of the second layer includes the first bit line BL_A and the first complementary bit line BLB_A. The word line WL and a wiring 208 formed in the second layer are connected to each other by contacts 203 and 211.

The wiring (Back side metal) formed on a back surface side of the substrate 201 of the SRAM 100 includes two power supply voltages VDD, the second bit line BL_B, and the second complementary bit line BLB_B. In the wiring on the back surface side, the second bit line BL_B and the second complementary bit line BLB_B are disposed on a center side of the SRAM 100, and the two power supply voltages VDD are disposed outside the second bit line BL_B and outside the second complementary bit line BLB_B, respectively.

As illustrated in FIG. 4, in the cross-sectional view taken along line A-A of FIG. 3, the contact metal 133 and the contact metal 134 are formed on the substrate 201. The contact metal 123 is formed above the contact metal 133, and the contact metal 124 is formed above the contact metal 134. The contact metal 133 and the contact metal 123 are connected to each other by a wiring 137. The wiring 137 functions as an output node Q of the first inverter INV1. The contact metal 134 and the contact metal 124 are connected to each other by a wiring 138. The wiring 138 functions as an output node QB of the second inverter INV2.

As illustrated in FIG. 3, the gate electrode 101 and the contact metal 124 are connected to each other by the gate contact metal 127. The gate electrode 104 and the contact metal 123 are connected to each other by the gate contact metal 128.

Therefore, the semiconductor layer 105 of the transistor PD1, the semiconductor layer 115 of the transistor PU1, the semiconductor layer 107 of the transistor PG1, the semiconductor layer 117 of the transistor PG2, and the gate electrode 104 shared by the transistor PD2 and the transistor PU2 are electrically connected to each other by the output node Q via the contact metals 123 and 133 and the gate contact metal 128.

In addition, the semiconductor layer 108 of the transistor PD2, the semiconductor layer 118 of the transistor PU2, the semiconductor layer 106 of the transistor PG3, the semiconductor layer 116 of the transistor PG4, and the gate electrode 101 shared by the transistor PD1 and the transistor PU1 are electrically connected to each other by the output node QB via the contact metals 124 and 134 and the gate contact metal 127.

As illustrated in FIG. 5, in the cross-sectional view taken along line B-B of FIG. 3, the gate electrode 101 and the gate electrode 102 are formed on the substrate 201. Furthermore, on a lower layer side of the CFET, the semiconductor layer 115 is formed in the gate electrode 101, and the semiconductor layer 116 is formed in the gate electrode 102. On an upper layer side of the CFET, the semiconductor layer 105 is formed in the gate electrode 101, and the semiconductor layer 106 is formed in the gate electrode 102.

As illustrated in FIG. 5, in the SRAM 100, in the transistor PD1, the transistor PU1, the transistor PG3, and the transistor PG4, peripheries of the semiconductor layers 105, 106, 115, and 116 constituting a channel region in a cross section in a gate width direction are covered with the gate electrodes 101 and 102. In addition, in the SRAM 100, in the transistor PG1, the transistor PG2, the transistor PD2, and the transistor PU2 which are not illustrated in the cross-sectional view of FIG. 5, peripheries of the semiconductor layers 107, 108, 117, and 118 constituting a channel region in a cross section in a gate width direction are covered with the gate electrodes 103 and 104. That is, each of the transistors PD1, PU1, PD2, PU2, PG1, PG2, PG3, and PG4 constituting the SRAM 100 is a gate all around (GAA)-FET having a nanosheet structure. The example of the SRAM 100 illustrated in FIG. 5 illustrates an example in which three semiconductor layers 105, three semiconductor layers 106, three semiconductor layers 115, and three semiconductor layers 116 are formed.

As illustrated in FIG. 5, the wiring 208 formed in the second layer and the gate electrode 102 of the transistors PG3 and PG4 are connected to each other by a contact 204. Therefore, in the SRAM 100, the word line WL and the gate electrode 102 are connected to each other via the wiring 208 and the contacts 203 and 204.

Although not illustrated, in the SRAM 100, the gate electrode 103 of the transistors PG1 and PG2 is similarly connected to the word line WL via the contact 211, a contact (not illustrated) having the same height as the contact 204, and the wiring 208 of the second layer.

As illustrated in FIG. 6, in the cross-sectional view taken along line C-C of FIG. 3, the contact metal 131 and the contact metal 132 are formed on the substrate 201. The contact metal 121 is formed above the contact metal 131, and the contact metal 122 is formed above the contact metal 132. The contact metal 131 and the contact metal 121 are separated from each other by an insulating layer or the like, and the contact metal 132 and the contact metal 122 are separated from each other by an insulating layer or the like.

In addition, as illustrated in FIG. 6, the reference potential VSS is disposed in the wiring (Metal 1) of the uppermost layer of the SRAM 100. The reference potential VSS and the wiring 208 of the second layer are connected to each other by a contact 205. In addition, the wiring 208 of the second layer and the contact metal 131 are connected to each other by a contact 207. Therefore, the contact metal 121 connected to the semiconductor layer 105 (source/drain) of the transistor PD1 is connected to the reference potential VSS via the wiring 208 of the second layer and the contacts 205 and 207.

The first complementary bit line BLB_A formed in the second layer of the SRAM 100 and the contact metal 122 connected to the semiconductor layer 106 (source/drain) of the transistor PG3 are connected to each other by a contact 206.

The second complementary bit line BLB_B disposed on a back surface side of the SRAM 100 and the contact metal 132 connected to the semiconductor layer 116 (source/drain) of the transistor PG4 are connected to each other via a contact 209 penetrating the substrate 201.

The power supply voltage VDD disposed on the back surface side of the SRAM 100 and the contact metal 131 connected to the semiconductor layer 115 (source/drain) of the transistor PU1 are connected to each other via a contact 210 penetrating the substrate 201.

Although not illustrated, in the SRAM 100, the contact metal 125 connected to the semiconductor layer 107 (source/drain) of the transistor PG1 is connected to the first bit line BL_A disposed in the second layer via a contact. The contact metal 126 connected to the semiconductor layer 108 (source/drain) of the transistor PD2 is connected to the reference potential VSS via a wiring of the second layer and a contact. The contact metal 135 connected to the semiconductor layer 117 (source/drain) of the transistor PG2 is connected to the second bit line BL_B via a contact penetrating the substrate 201. The contact metal 136 connected to the semiconductor layer 118 (source/drain) of the transistor PU2 is connected to the power supply voltage VDD via a contact penetrating the substrate 201.

With the above configuration, the dual port SRAM in the equivalent circuit diagram illustrated in FIG. 1 can be achieved by a CFET structure in which nanosheet transistors having GAA-FET structures are stacked in a vertical direction.

Therefore, it is possible to provide a semiconductor device capable of improving an integration density as compared with a SRAM to which a FinFET structure is applied. In addition, a dual port SRAM having an 8Tr configuration in which a CFET structure is also applied to a pass gate transistor can be formed in the same area as a single port SRAM having a 6Tr configuration in which the CFET structure is applied to a transistor other than the pass gate transistor. Therefore, an integration density of a semiconductor device can be improved.

Note that the SRAM 100 illustrated in FIGS. 3 to 6 described above can be manufactured using a nanosheet transistor, a CFET manufacturing method, and a material, which are conventionally known.

### [Threshold Voltage Vth of Pass Gate Transistor]

Next, threshold voltages Vth of the transistor PG1, the transistor PG2, the transistor PG3, and the transistor PG4 will be described.

As described above, the SRAM 100 includes the transistors PG1 and PG3 formed of NMOS and the transistors PG2 and PG4 formed of PMOS. In the SRAM 100, a threshold voltage Vth is set for the NMOS transistors PG1 and PG3, and a threshold voltage Vth is set for the PMOS transistors PG2 and PG4.

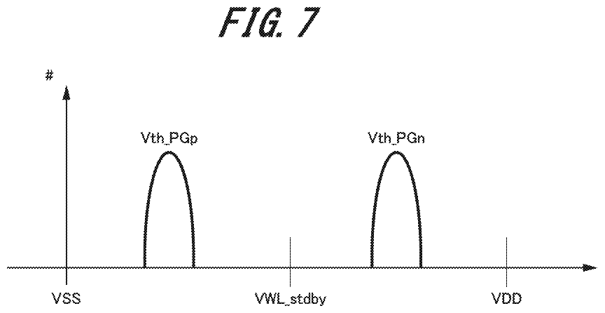

FIG. 7 illustrates a relationship among a threshold voltage Vth_PGn of the NMOS transistors PG1 and PG3, a threshold voltage Vth_PGp of the PMOS transistors PG2 and PG4, and a standby voltage VWL_stdby of a word line WL. In FIG. 7, the horizontal axis represents a voltage, and represents a voltage from the reference potential VSS to the power supply voltage VDD.

As illustrated in FIG. 7, the voltage of the word line WL at the time of standby is set to the standby voltage VWL_stdby. That is, the standby voltage of the word line WL is set between the voltage of the power supply voltage VDD and the voltage of the reference potential VSS. As illustrated in FIG. 7, the standby voltage VWL_stdby of the word line WL is preferably set to about ½ of the power supply voltage VDD.

The threshold voltage Vth_PGn of the NMOS transistors PG1 and PG3 is made larger than the standby voltage VWL_stdby of the word line WL. That is, the threshold voltage Vth_PGn is set to satisfy a relationship of [VWL_stdby<Vth_PGn]. By making the threshold voltage Vth_PGn larger than VWL_stdby, the transistors PG1 and PG3 are prevented from operating in a standby state. In a case where the transistors PG1 and PG3 are operated, a gate voltage applied from the word line WL to the NMOS transistors PG1 and PG3 is increased from the standby voltage VWL_stdby. Then, when the gate voltage from the word line WL reaches the threshold voltage Vth_PGn, the NMOS transistors PG1 and PG3 operate.

In addition, the threshold voltage Vth_PGp of the PMOS transistors PG2 and PG4 is made smaller than the standby voltage VWL_stdby of the word line WL, and the threshold voltage Vth_PGp is set to satisfy a relationship of [VWL_stdby>Vth_PGp]. By making the threshold voltage Vth_PGp smaller than VWL_stdby, the transistors PG2 and PG4 are prevented from operating in a standby state. In a case where the transistors PG2 and PG4 are operated, a gate voltage applied from the word line WL to the PMOS transistors PG2 and PG3 is decreased from the standby voltage VWL_stdby. Then, when the gate voltage from the word line WL decreases to the threshold voltage Vth_PGp, the PMOS transistors PG2 and PG4 operate.

Therefore, the SRAM 100 includes the transistors PG1, PG2, PG3, and PG4 each having a threshold voltage Vth satisfying [VWL_stdby<Vth_PGn] and [VWL_stdby>Vth_PGp]. With this configuration, the NMOS transistors PG1 and PG3 and the PMOS transistors PG2 and PG4 sharing gate electrodes can be individually operated.

### [Word Line and Sense Amplifier]

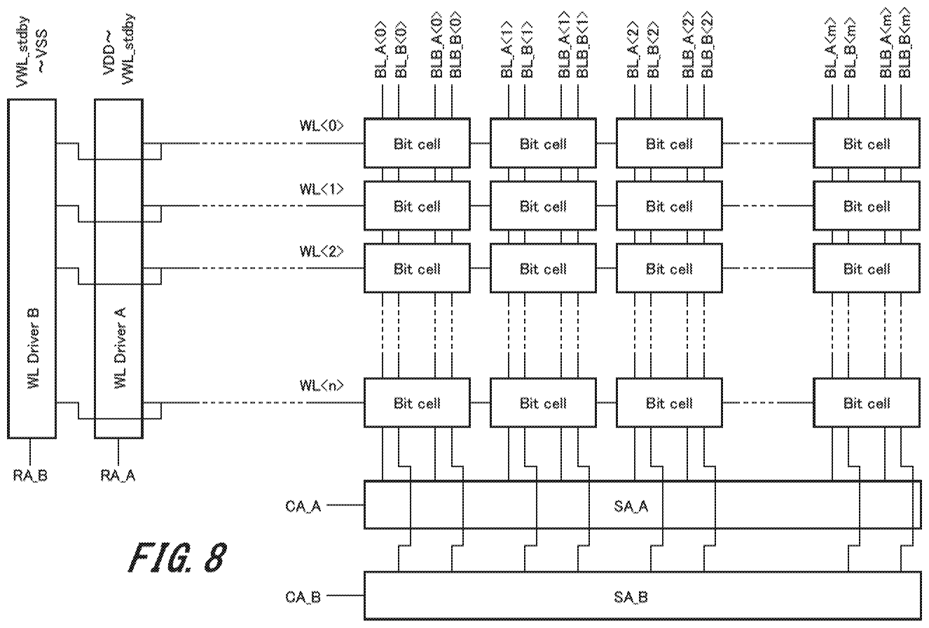

Next, connection between a word line WL of the SRAM 100 and a sense amplifier will be described. FIG. 8 illustrates a planar arrangement diagram of a SRAM array including a word line and a sense amplifier.

As illustrated in FIG. 8, the SRAM 100 includes a word line driver A (WL Driver A) and a word line driver B (WL Driver B). The word line driver A receives a row address RA_A. The word line driver B receives a row address RA_B.

The SRAM 100 includes a sense amplifier SA_A and a sense amplifier SA_B. The sense amplifier SA_A receives a column address CA_A. The sense amplifier SA_B receives a column address CA_B.

The word line driver A (WL Driver A) and the word line driver B (WL Driver B) operate in different voltage ranges between ports. That is, the word line driver A (WL Driver A) and the word line driver B (WL Driver B) have different circuits. The sense amplifier SA_A and the sense amplifier SA_BSA operate in different voltage ranges between ports. That is, the sense amplifier SA_A and the sense amplifier SA_B have different circuits.

In the SRAM 100, bit cells are connected to the word line driver A (WL Driver A) and the word line driver B (WL Driver B) by word lines WL. The dual port SRAM cannot access physically the same word line WL doubly. That is, the NMOS transistors PG1 and PG3 (port A) access either one of the word line driver A (WL Driver A) and the word line driver B (WL Driver B), and the PMOS transistors PG2 and PG4 (port B) access the other one of the word line driver A (WL Driver A) and the word line driver B (WL Driver B).

In addition, in the dual port SRAM, the same row address is prohibited between ports. Therefore, different row addresses are designated for the NMOS transistors PG1 and PG3 (port A) and the PMOS transistors PG2 and PG4 (port B).

In the SRAM 100, bit cells are connected to the sense amplifier SA_A and the sense amplifier SA_B by the first bit line BL_A, the first complementary bit line BLB_A, the second bit line BL_B, and the second complementary bit line BLB_B. The dual port SRAM is connected to the sense amplifier SA_A or the sense amplifier SA_B, which is varied depending on a port. That is, the first bit line pair consisting of the first bit line BL_A and the first complementary bit line BLB_A is connected to the sense amplifier SA_A. The second bit line pair consisting of the second bit line BL_B and the second complementary bit line BLB_B is connected to the sense amplifier SA_B. Therefore, the NMOS transistors PG1 and PG3 are connected to the sense amplifier SA_A via the first bit line pair. The PMOS transistors PG2 and PG4 are connected to the sense amplifier SA_B via the second bit line pair.

### [Simple Timing Chart of Read]

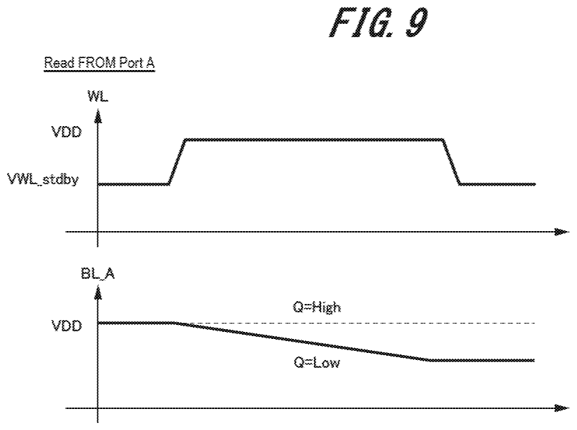

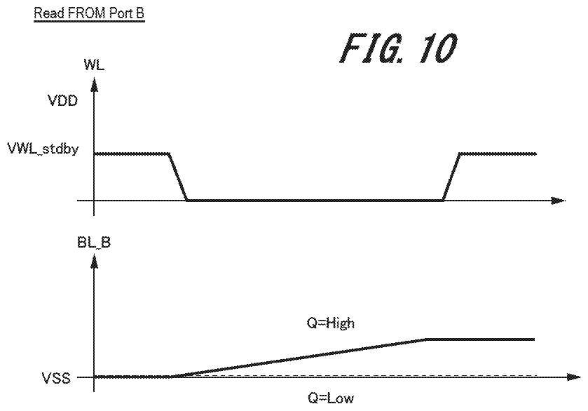

Next, Read of the SRAM 100 will be described. FIGS. 9 and 10 illustrate simple timing charts of Read of the SRAM 100. FIG. 9 is a simple timing chart when Read is performed from the port A. FIG. 10 is a simple timing chart when Read is performed from the port B. In FIGS. 9 and 10, the vertical axis represents voltage (potential), and the horizontal axis represents time.

As illustrated in FIG. 9, in the SRAM 100 before start of Read, a gate voltage from a word line WL to the transistors PG1 and PG3 is the standby voltage VWL_stdby. In the SRAM 100 before start of Read, a potential of the first bit line BL_A is the power supply voltage VDD.

As illustrated in FIG. 10, in the SRAM 100 before start of Read, a gate voltage from a word line WL to the transistors PG2 and PG4 is the standby voltage VWL_stdby. In the SRAM 100 before start of Read, a potential of the second bit line BL_B is the reference potential VSS.

In a case where Read is performed from the port A, that is, the NMOS transistors PG1 and PG3, as illustrated in FIG. 9, a gate voltage supplied from the word line WL to the transistors PG1 and PG3 is made larger than the standby voltage VWL_stdby of the word line WL. By making the voltage from the word line WL larger, the first bit line BL_A is precharged to High. Thereafter, if the output node Q=Low, the potential of the first bit line BL_A decreases. When the potential of the first bit line BL_A decreases and a potential difference that can be read by the sense amplifier SA_A is generated between the first bit line BL_A and the power supply voltage VDD, Read of data of the first inverter INV1 and the second inverter INV2 from the port A is possible.

In a case where Read is performed from the port B, that is, the PMOS transistors PG2 and PG4, as illustrated in FIG. 10, a gate voltage supplied from the word line WL to the transistors PG2 and PG4 is made smaller than the standby voltage VWL_stdby of the word line WL. By making the voltage from the word line WL smaller, the second bit line BL_B is precharged to Low. Thereafter, if the output node Q=High, the potential of the second bit line BL_B increases. When the potential of the second bit line BL_B increases and a potential difference that can be read by the sense amplifier SA_B is generated between the second bit line BL_B and the reference potential VSS, Read of data of the first inverter INV1 and the second inverter INV2 from the port B is possible.

### [Simple Timing Chart of Write]

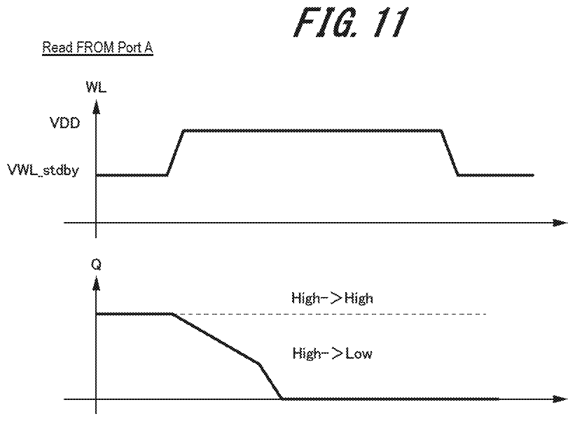

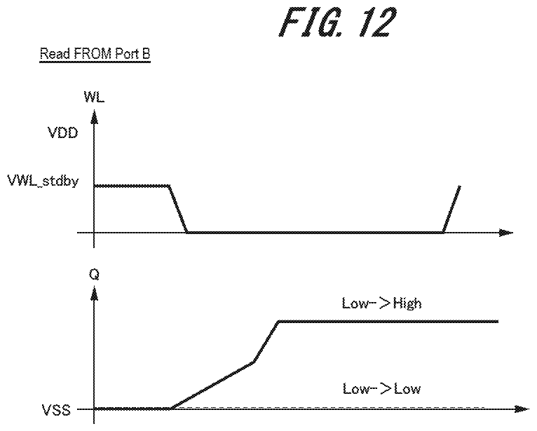

Next, Write of the SRAM 100 will be described. FIGS. 11 and 12 illustrate simple timing charts of Write of the SRAM 100. FIG. 11 is a timing chart when Write is performed from the port A. FIG. 12 is a timing chart when Write is performed from the port B. In FIGS. 11 and 12, the vertical axis represents voltage (potential), and the horizontal axis represents time.

As illustrated in FIG. 11, in the SRAM 100 before start of Write, a gate voltage from a word line WL to the transistors PG1 and PG3 is the standby voltage VWL_stdby. Similarly, as illustrated in FIG. 12, in the SRAM 100 before start of Write, a gate voltage from the word line WL to the transistors PG2 and PG4 is the standby voltage VWL_stdby.

In a case where Write is performed from the port A, that is, the NMOS transistors PG1 and PG3, as illustrated in FIG. 11, a gate voltage supplied from the word line WL to the transistors PG1 and PG3 is made larger than the standby voltage VWL_stdby of the word line WL. By making the voltage from the word line WL larger, the output node Q is pulled to a Low potential through the first bit line BL_A. When the potential of the output node Q becomes lower than a trip potential of a data latch in the SRAM 100, the data of the first inverter INV1 and the second inverter INV2 is inverted. As a result, Write of data from the port A to the first inverter INV1 and the second inverter INV2 is possible.

In a case where Write is performed from the port B, that is, the PMOS transistors PG2 and PG4, as illustrated in FIG. 12, a gate voltage supplied from the word line WL to the transistors PG2 and PG4 is made smaller than the standby voltage VWL_stdby of the word line WL. By making the voltage from the word line WL smaller, the output node Q is raised to a High potential through the second bit line BL_B. When the potential of the output node Q becomes higher than a trip potential of a data latch in the SRAM 100, the data of the first inverter INV1 and the data of the second inverter INV2 are inverted. As a result, Write of data from the port B to the first inverter INV1 and the second inverter INV2 is possible.

### 2. Second Embodiment of Semiconductor Device

Next, a second embodiment of the semiconductor device will be described. The semiconductor device of the second embodiment has a configuration in which the conductivity type of the transistor formed in the upper layer of the CFET and the conductivity type of the transistor formed in the lower layer of the CFET are reversed in the semiconductor device of the first embodiment described above. The semiconductor device of the second embodiment is similar to the semiconductor device of the first embodiment described above except that the conductivity type is changed. Therefore, detailed description of a similar configuration to that of the semiconductor device of the first embodiment described above is omitted.

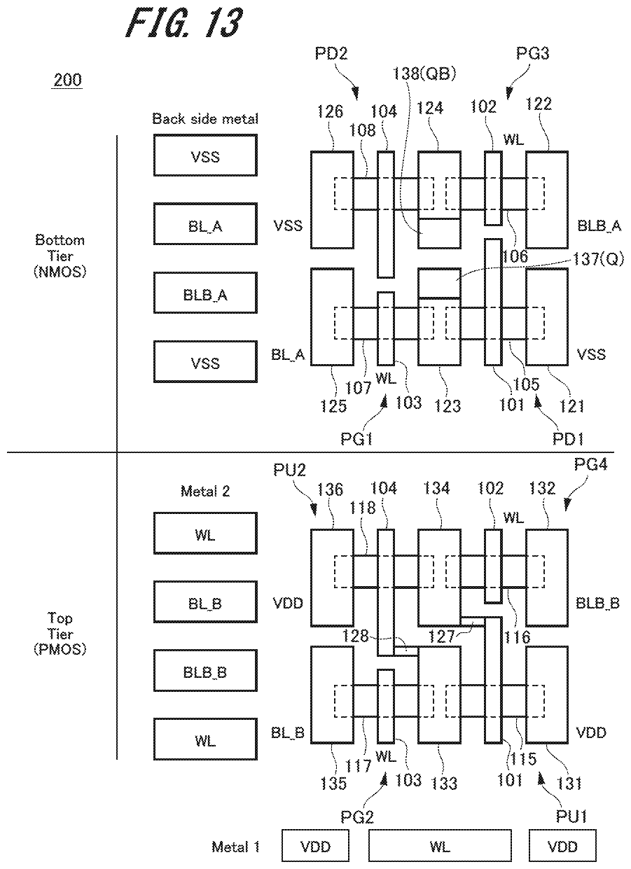

As an example of the semiconductor device of the second embodiment, a planar arrangement diagram of transistors of a SRAM 200 is illustrated in FIG. 13. Note that the cross-sectional view of the SRAM 200 illustrated in FIG. 13 is similar to the structure illustrated in FIGS. 4, 5, and 6 described above except for the conductivity type of the transistor and the position of each wiring.

As illustrated in FIG. 13, the SRAM 200 indicates planar arrangement of a GAA-FET having a nanosheet structure disposed on an upper layer (Top Tier) of a CFET and a planar arrangement of a GAA-FET having a nanosheet structure disposed on a lower layer (Bottom Tier) of the CFET.

In the SRAM 200, a transistor PU1, a transistor PG2, a transistor PU2, and a transistor PG4 which are each formed of PMOS are disposed on the upper layer side of the CFET. In the SRAM 200, a transistor PD1, a transistor PG1, a transistor PD2, and a transistor PG3 which are each formed of NMOS are disposed on the lower layer side of the CFET.

In the SRAM 200 illustrated in FIG. 13, the transistor PU1 is formed above the transistor PD1. The transistor PG2 is formed above the transistor PG1. The transistor PU2 is formed above the transistor PD2. The transistor PG4 is formed above the transistor PG3.

The SRAM 200 includes two power supply voltages VDD and a word line WL as a wiring (Metal 1) of an uppermost layer (first layer) of the CFET. The SRAM 200 includes two word lines WL, a second bit line BL_B, and a second complementary bit line BLB_B as a wiring (Metal 2) of the second layer of the CFET. Furthermore, the SRAM 200 includes two reference potentials VSS, a first bit line BL_A, and a first complementary bit line BLB_A as a wiring (Back side metal) on a back surface side of the CFET.

Similarly to the first embodiment, gate electrodes 101, 102, 103, and 104 are continuously formed on the upper layer and the lower layer of the CFET. That is, the transistor PD1 and the transistor PU1 have the common gate electrode 101. Similarly, the transistor PG1 and the transistor PG2 have the common gate electrode 103. The transistor PD2 and the transistor PU2 have the common gate electrode 104. The transistor PG3 and the transistor PG4 have the common gate electrode 102.

The gate electrode 103 shared by the transistor PG1 and the transistor PG2 is connected to a word line WL. Similarly, the gate electrode 102 shared by the transistor PG3 and the transistor PG4 is connected to a word line WL.

The transistor PD1 includes a channel, a semiconductor layer 105 serving as a source/drain, and the gate electrode 101. At one end of the semiconductor layer 105 serving as a source/drain of the transistor PD1, a contact metal 121 that connects the source/drain and the reference potential VSS to each other is disposed. At the other end of the semiconductor layer 105, a contact metal 123 that connects the source/drain of the transistor PD1 and a source/drain of the transistor PG1 to each other is disposed.

The transistor PG1 includes a channel, a semiconductor layer 107 serving as a source/drain, and the gate electrode 103. At one end of the semiconductor layer 107 serving as a source/drain of the transistor PG1, a contact metal 125 that connects the source/drain of the transistor PG1 and the first bit line BL_A to each other is disposed. At the other end of the semiconductor layer 107, the contact metal 123 that connects the source/drain of the transistor PG1 and the source/drain of the transistor PD1 to each other is disposed.

The transistor PG3 includes a channel, a semiconductor layer 106 serving as a source/drain, and the gate electrode 102. At one end of the semiconductor layer 106 serving as a source/drain of the transistor PG3, a contact metal 122 that connects the source/drain and the first complementary bit line BLB_A to each other is disposed. At the other end of the semiconductor layer 106, a contact metal 124 that connects the source/drain of the transistor PG3 and a source/drain of the transistor PD2 to each other is disposed.

The transistor PD2 includes a channel, a semiconductor layer 108 serving as a source/drain, and the gate electrode 104. At one end of the semiconductor layer 108 serving as a source/drain of the transistor PD2, a contact metal 126 that connects the source/drain and the reference potential VSS to each other is disposed. At the other end of the semiconductor layer 108, the contact metal 124 that connects the source/drain of the transistor PD2 and the source/drain of the transistor PG3 to each other is disposed.

The transistor PU1 includes a channel, a semiconductor layer 115 serving as a source/drain, and the gate electrode 101. At one end of the semiconductor layer 115 serving as a source/drain of the transistor PU1, a contact metal 131 that connects the source/drain of the transistor PU1 and the power supply voltage VDD to each other is disposed. At the other end of the semiconductor layer 115, a contact metal 133 that connects the source/drain of the transistor PU1 and a source/drain of the transistor PG2 to each other is disposed.

The transistor PG2 includes a channel, a semiconductor layer 117 serving as a source/drain, and the gate electrode 103. At one end of the semiconductor layer 117 serving as a source/drain of the transistor PG2, a contact metal 135 that connects the source/drain and the second bit line BL_B to each other is disposed. At the other end of the semiconductor layer 117, the contact metal 133 that connects the source/drain of the transistor PG2 and the source/drain of the transistor PU1 to each other is disposed.

The transistor PG4 includes a channel, a semiconductor layer 116 serving as a source/drain, and the gate electrode 102. At one end of the semiconductor layer 116 serving as a source/drain of the transistor PG4, a contact metal 132 that connects the source/drain and the second complementary bit line BLB_B to each other is disposed. At the other end of the semiconductor layer 116, a contact metal 134 that connects the source/drain of the transistor PG4 and a source/drain of the transistor PU2 to each other is disposed.

The transistor PU2 includes a channel, a semiconductor layer 118 serving as a source/drain, and the gate electrode 104. At one end of the semiconductor layer 118 serving as a source/drain of the transistor PU2, a contact metal 136 that connects the source/drain and the power supply voltage VDD to each other is disposed. At the other end of the semiconductor layer 118, the contact metal 134 that connects the source/drain of the transistor PU2 and the source/drain of the transistor PG4 to each other is disposed.

As illustrated in FIG. 13, the contact metal 123 and the contact metal 133 are connected to each other by a wiring 137. The wiring 137 functions as an output node Q of the first inverter INV1. The contact metal 124 and the contact metal 134 are connected to each other by a wiring 138. The wiring 138 functions as an output node QB of the second inverter INV2.

As illustrated in FIG. 13, the gate electrode 101 and the contact metal 134 are connected to each other by the gate contact metal 127. The gate electrode 104 and the contact metal 133 are connected to each other by the gate contact metal 128.

Therefore, the semiconductor layer 105 of the transistor PD1, the semiconductor layer 115 of the transistor PU1, the semiconductor layer 107 of the transistor PG1, the semiconductor layer 117 of the transistor PG2, and the gate electrode 104 shared by the transistor PD2 and the transistor PU2 are electrically connected to each other by the output node Q via the contact metals 123 and 133 and the gate contact metal 128.

In addition, the semiconductor layer 108 of the transistor PD2, the semiconductor layer 118 of the transistor PU2, the semiconductor layer 106 of the transistor PG3, the semiconductor layer 116 of the transistor PG4, and the gate electrode 101 shared by the transistor PD1 and the transistor PU1 are electrically connected to each other by the output node QB via the contact metals 124 and 134 and the gate contact metal 127.

With the above configuration, the SRAM 200 of the second embodiment can be achieved. The circuit diagram of the SRAM 200 is similar to the circuit diagram of the above-described first embodiment illustrated in FIG. 1. As described above, also with the configuration of the semiconductor device of the second embodiment, a dual port SRAM having a CFET structure in which nanosheet transistors having GAA-FET structures are stacked in a vertical direction can be constituted. The semiconductor device of the second embodiment has a similar effect to that of the semiconductor device of the first embodiment.

### 3. Third Embodiment of Semiconductor Device

Next, a third embodiment of the semiconductor device will be described. In the semiconductor device of the third embodiment, a voltage of a bit line before and after Read and before and after Write, that is, a standby voltage of the bit line is changed to a setting different from that of the first embodiment. To the semiconductor device of the third embodiment, the configurations of the first embodiment and the second embodiment described above can be applied except that the standby voltage of the bit line is changed. Therefore, detailed description of a similar configuration to those of the semiconductor devices of the first embodiment and the second embodiment described above is omitted.

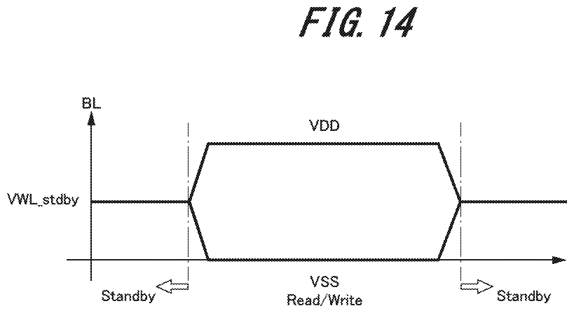

FIG. 14 illustrates a simple timing chart of Read and Write of a SRAM of the third embodiment. In FIG. 14, the vertical axis represents voltage (potential), and the horizontal axis represents time. FIG. 14 illustrates changes in potentials of a first bit line BL_A and a second bit line BL_B in Read and Write processes.

As illustrated in FIG. 14, in the first bit line BL_A and the second bit line BL_B of the SRAM, a standby voltage before start of Read or Write operation (Standby) is set to a standby voltage VWL_stdby of a word line WL. Then, during the Read or Write operation (Read/Write), the potential of the first bit line BL_A is lowered to a reference potential VSS. In addition, during the Read or Write operation (Read/Write), the potential of the second bit line BL_B is raised to a power supply voltage VDD.

In the standby voltage after end of Read or Write operation (Standby), the potentials of the first bit line BL_A and the second bit line BL_B return to the standby voltage VWL_stdby of the word line WL again.

As described above, in the SRAM of the third embodiment, the potentials of the first bit line BL_A and the second bit line BL_B are set to about the same level as the standby voltage VWL_stdby of the word line WL before and after Read and before and after Write.

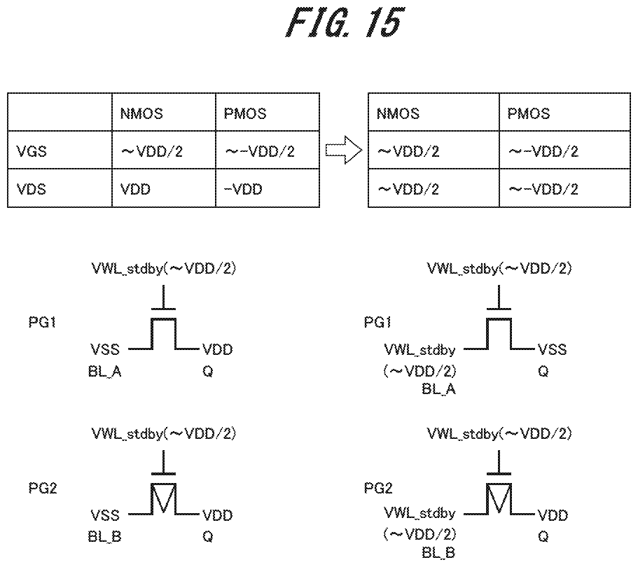

FIG. 15 illustrates a comparison between a standby voltage of a bit line in the SRAM of the third embodiment and a standby voltage of a bit line in the SRAM of the above-described first embodiment. In FIG. 15, the table and the drawing on the left side of the arrow indicate the standby voltage of the bit line in the SRAM of the first embodiment, and the right side of the arrow indicates the standby voltage of the bit line in the SRAM of the third embodiment.

In addition, FIG. 15 illustrates a combination of potentials when a leakage current is maximized in a transistor PG1 connected to the first bit line BL_A and a transistor PG2 connected to the second bit line BL_B.

As illustrated in FIG. 15, in the standby voltage of the bit line in the above-described first embodiment, the leakage current is maximized when the potential of the first bit line BL_A is the power supply voltage VDD and the potential of the output node Q is the reference potential VSS. At this time, in the NMOS transistor PG1, a gate-source voltage VGS is about the same as a half (VDD/2) of the power supply voltage VDD at a maximum, and a drain-source voltage VDS is about the same as the power supply voltage VDD. In the PMOS transistor PG2, a gate-source voltage VGS is about the same as a half (−VDD/2) of a negative value of the power supply voltage VDD at a maximum, and a drain-source voltage VDS is about the same as a negative value (−VDD) of the power supply voltage VDD.

On the other hand, in the SRAM of the third embodiment, the standby voltage of the bit line is set to be about the same level as the standby voltage VWL_stdby of the word line WL. Therefore, in the standby voltage of the bit line, the leakage current is maximized when the potential of the first bit line BL_A is the standby voltage VWL_stdby and the potential of the output node Q is the reference potential VSS. At this time, in the NMOS transistor PG1, a gate-source voltage VGS is about the same as a half (VDD/2) of the power supply voltage VDD at a maximum, and a drain-source voltage VDS is about the same as a half (VDD/2) of the power supply voltage VDD. In the PMOS transistor PG2, a gate-source voltage VGS is about the same as a half (−VDD/2) of a negative value of the power supply voltage VDD at a maximum, and a drain-source voltage VDS is about the same as a half (−VDD/2) of a negative value of the power supply voltage VDD.

As described above, in the SRAM of the third embodiment, the gate-source voltages VGS of the transistors PG1 and PG2 are similar to those of the SRAM of the first embodiment. However, while the drain-source voltage VDS of the transistor PG1 of the SRAM of the first embodiment is VDD, the drain-source voltage VDS of the transistor PG1 of the SRAM of the third embodiment decreases to (VDD/2). Furthermore, while the drain-source voltage VDS of the transistor PG2 of the SRAM of the first embodiment is −VDD, the drain-source voltage VDS of the transistor PG2 of the SRAM of the third embodiment decreases to (−VDD/2).

As described above, in the SRAM of the third embodiment, the standby voltage of the bit line is set to about the same level as the standby voltage VWL_stdby of the word line WL, and therefore the leakage currents of the transistor PG1 and the transistor PG2 can be reduced.

Note that, in the third embodiment described above, the first bit line BL_A, the second bit line BL_B, the transistor PG1, and the transistor PG2 have been described, but a first complementary bit line BL_A, a second complementary bit line BL_B, a transistor PG3, and a transistor PG4 can also be set in a similar manner.

Note that the present invention is not limited to the configurations described in the above-described embodiments, and various modifications and changes can be made without departing from the configuration of the present invention.

### REFERENCE SIGNS LIST

100, 200 SRAM
101, 102, 103, 104 Gate electrode
105, 106, 107, 108, 115, 116, 117, 118 Semiconductor layer
121, 122, 123, 124, 125, 126, 131, 132, 133, 134, 135, 136 Contact metal
127, 128 Gate contact metal
137, 138, 208 Wiring
201 Substrate
202 Insulating layer
203, 204, 205, 206, 207, 209, 210, 211 Contact
INV1 First inverter
INV2 Second inverter
PD1, PD2, PG1, PG2, PG3, PG4, PU1, PU2 Transistor

1. A semiconductor device comprising:
a first inverter and a second inverter that are cross-connected;
a first conductivity type first pass gate transistor disposed between a first bit line and the first and second inverters;
a second conductivity type second pass gate transistor disposed between a second bit line and the first and second inverters;
a first conductivity type third pass gate transistor disposed between a first complementary bit line and the first and second inverters; and
a second conductivity type fourth pass gate transistor disposed between a second complementary bit line and the first and second inverters, wherein
the first pass gate transistor and the second pass gate transistor share a first gate connected to a word line, and
the third pass gate transistor and the fourth pass gate transistor share a second gate connected to the word line.

2. The semiconductor device according to claim 1, wherein
the first pass gate transistor, the second pass gate transistor, the third pass gate transistor, and the fourth pass gate transistor are nanosheet semiconductor elements.

3. The semiconductor device according to claim 2, wherein
the first pass gate transistor and the second pass gate transistor are stacked, and
the third pass gate transistor and the fourth pass gate transistor are stacked.

4. The semiconductor device according to claim 3, wherein
the first inverter includes a first conductivity type first pull-down transistor and a second conductivity type first pull-up transistor that are stacked, and
the second inverter includes a first conductivity type second pull-down transistor and a second conductivity type second pull-up transistor that are stacked, and
the first pull-down transistor, the first pull-up transistor, the second pull-down transistor, and the second pull-up transistor are nanosheet semiconductor elements.

5. The semiconductor device according to claim 4, comprising
a substrate on which the first pass gate transistor, the second pass gate transistor, the third pass gate transistor, the fourth pass gate transistor, the first pull-down transistor, the first pull-up transistor, the second pull-down transistor, and the second pull-up transistor are formed, wherein
the first pull-up transistor, the second pull-up transistor, the second pass gate transistor, and the fourth pass gate transistor are disposed on the substrate side, and
the first pull-down transistor, the second pull-down transistor, the first pass gate transistor, and the third pass gate transistor are disposed on the first pull-up transistor, the second pull-up transistor, the second pass gate transistor, and the fourth pass gate transistor.

6. The semiconductor device according to claim 4, comprising
a substrate on which the first pass gate transistor, the second pass gate transistor, the third pass gate transistor, the fourth pass gate transistor, the first pull-down transistor, the first pull-up transistor, the second pull-down transistor, and the second pull-up transistor are formed, wherein
the first pull-down transistor, the second pull-down transistor, the first pass gate transistor, and the third pass gate transistor are disposed on the substrate side, and
the first pull-up transistor, the second pull-up transistor, the second pass gate transistor, and the fourth pass gate transistor are disposed on the first pull-down transistor, the second pull-down transistor, the first pass gate transistor, and the third pass gate transistor.

7. The semiconductor device according to claim 1, wherein
in the first pass gate transistor and the second pass gate transistor that are stacked and the third pass gate transistor and the fourth pass gate transistor that are stacked, the first bit line and the first complementary bit line are disposed on one surface side in a stacking direction, and the second bit line and the second complementary bit line are disposed on the other surface.

8. The semiconductor device according to claim 1, wherein
a voltage higher than a standby voltage is supplied from the word line to the first gate or the second gate, and data of the first inverter and the second inverter is read from the first pass gate transistor and the second pass gate transistor by lowering potentials of the first bit line and the first complementary bit line, and
a voltage lower than a standby voltage is supplied from the word line to the first gate or the second gate, and data of the first inverter and the second inverter is read from the third pass gate transistor and the fourth pass gate transistor by raising potentials of the second bit line and the second complementary bit line.

9. The semiconductor device according to claim 1, wherein
a voltage higher than a standby voltage is supplied from the word line to the first gate or the second gate, and data is written to the first inverter and the second inverter from the first pass gate transistor and the second pass gate transistor by lowering potentials of the first bit line and the first complementary bit line, and
a voltage lower than a standby voltage is supplied from the word line to the first gate or the second gate, and data is written to the first inverter and the second inverter from the third pass gate transistor and the fourth pass gate transistor by raising potentials of the second bit line and the second complementary bit line.

10. The semiconductor device according to claim 1, wherein
potentials of the first bit line, the first complementary bit line, the second bit line, and the second complementary bit line are set to a standby voltage of the word line before and after data of the first inverter and the second inverter is read and before and after data is written to the first inverter and the second inverter.
